(19) United States
(12) Patent Application Publication
(10) Pub. No.: US 2026/0120770 A1
(43) Pub. Date: Apr. 30, 2026

(54) METHOD AND APPARATUS FOR PROGRAM VOLTAGE MANAGEMENT IN MEMORY SYSTEMS

(71) Applicant: Yangtze Memory Technologies Co., Ltd., Wuhan (CN)

(72) Inventors: Li XIANG, Wuhan (CN); Ke KE, Wuhan (CN); Wei HUANG, Wuhan (CN)

(21) Appl. No.: 19/014,938

(22) Filed: Jan. 9, 2025

Related U.S. Application Data
(63) Continuation of application No. PCT/CN2024/127998, filed on Oct. 29, 2024.

(51) Int. Cl. G11C 16/10; G11C 16/04; G11C 16/08; G11C 16/30

(52) U.S. Cl. CPC G11C 16/10; G11C 16/0483; G11C 16/08; G11C 16/30

(57) ABSTRACT

The present disclosure relates to program voltage management in memory devices and systems. An example method for programming memory cells of a memory device is provided. The method includes increasing a voltage of a first word line of the memory device from a first voltage to a second voltage in a first time period. The method further includes increasing the voltage of the first word line from the second voltage to a target program voltage in a second time period. The method further includes increasing a voltage of a second word line of the memory device from a third voltage to a fourth voltage. The second word line is adjacent to the first word line. The voltage of the second word line starts to increase from the third voltage after the voltage of the first word line reaches the second.

### CROSS-REFERENCE TO RELATED APPLICATIONS

This application is a continuation of International Application No. PCT/CN2024/127998, filed on Oct. 29, 2024, the disclosure of which is hereby incorporated by reference in its entirety.

### TECHNICAL FIELD

The present disclosure generally relates to memory devices and memory systems, and in particular, to program voltage management in memory devices and systems.

### BACKGROUND

Semiconductor memory devices can be categorized into volatile memory devices and non-volatile memory devices. The volatile memory devices lost data when power is off. The non-volatile memory devices can retain stored data when power is not connected. Flash memory is a low-cost and high-density non-volatile memory device, which includes NOR flash memory and NAND flash memory. Various operations, such as read, program (write), and erase, can be performed by the flash memory.

### SUMMARY

The present disclosure describes techniques for program voltage management in memory devices and systems.

One aspect of the present disclosure features a method for programming memory cells of a memory device. The method includes increasing a voltage of a first word line of the memory device from a first voltage to a second voltage in a first time period. The method further includes increasing the voltage of the first word line from the second voltage to a target program voltage in a second time period. The method further includes increasing a voltage of a second word line of the memory device from a third voltage to a fourth voltage. The second word line is adjacent to the first word line. The voltage of the second word line starts to increase from the third voltage after the voltage of the first word line reaches the second voltage and before the voltage of the first word line reaches the target program voltage.

In some implementations, the voltage of the first word line starts to increase from the second voltage and the voltage of the second word line starts to increase from the third voltage at a same time.

In some implementations, the voltage of the first word line starts to increase from the second voltage and the voltage of the second word line starts to increase from the third voltage at a beginning of the second time period.

In some implementations, the method further includes increasing a voltage of a third word line of the memory device from the first voltage to the fourth voltage in the first time period. The third word line is adjacent to the first word line.

In some implementations, memory cells coupled to the first word line are being programmed in a current program operation, memory cells coupled to the second word line have not been programmed in the current program operation yet, and memory cells coupled to the third word line have been programmed in the current program operation.

In some implementations, the method further includes increasing the voltage of the second word line from the fourth voltage to a first pass voltage in the second time period, and increasing the voltage of the third word line from the fourth voltage to a second pass voltage in the second time period. The first pass voltage is higher than the second pass voltage.

In some implementations, the voltage of the second word line and the voltage of the third word line start to increase from the fourth voltage at a same time.

In some implementations, the voltage of the second word line starts to increase from the third voltage after the voltage of the third word line reaches the fourth voltage.

In some implementations, the voltage of the second word line is kept at the third voltage during the first time period, and the third voltage is less than the first voltage.

In some implementations, the third voltage is less than or equal to 0 volt (V).

Another aspect of the present disclosure features a memory device. The memory device includes a memory block including a first word line and a second word line adjacent to the first word line, and a peripheral circuit including a voltage generator and a string driver. The peripheral circuit is configured to: increase a voltage of the first word line from a first voltage to a second voltage in a first time period; increase the voltage of the first word line from the second voltage to a target program voltage in a second time period; and increase a voltage of the second word line from a third voltage to a fourth voltage. The voltage of the second word line starts to increase from the third voltage after the voltage of the first word line reaches the second voltage and before the voltage of the first word line reaches the target program voltage.

In some implementations, the voltage of the first word line starts to increase from the second voltage and the voltage of the second word line starts to increase from the third voltage at a beginning of the second time period.

In some implementations, the memory block further includes a third word line adjacent to the first word line. The peripheral circuit is further configured to increase a voltage of the third word line from the first voltage to the fourth voltage in the first time period.

In some implementations, memory cells coupled to the first word line are being programmed in a current program operation, memory cells coupled to the second word line have not been programmed in the current program operation yet, and memory cells coupled to the third word line have been programmed in the current program operation.

In some implementations, the peripheral circuit is further configured to: increase the voltage of the second word line from the fourth voltage to a first pass voltage in the second time period; and increase the voltage of the third word line from the fourth voltage to a second pass voltage in the second time period.

In some implementations, the voltage of the second word line and the voltage of the third word line start to increase from the fourth voltage at a same time.

In some implementations, the voltage of the second word line starts to increase from the third voltage after the voltage of the third word line reaches the fourth voltage.

In some implementations, the third voltage is less than or equal to 0V.

In some implementations, the voltage of the second word line is kept at the third voltage during the first time period, and the third voltage is less than or equal to the first voltage.

A further aspect of the present disclosure features a memory system. The memory system includes a memory device and a memory controller configured to control the memory device. The memory device includes a memory block including a first word line and a second word line adjacent to the first word line, and a peripheral circuit including a voltage generator and a string driver. The peripheral circuit is configured to: increase a voltage of the first word line from a first voltage to a second voltage in a first time period; increase the voltage of the first word line from the second voltage to a target program voltage in a second time period; and increase a voltage of the second word line from a third voltage to a fourth voltage. The voltage of the second word line starts to increase from the third voltage after the voltage of the first word line reaches the second voltage and before the voltage of the first word line reaches the target program voltage.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates an example of a schematic diagram of a memory device including peripheral circuits.

FIG. 2 illustrates an example of a side view of cross-sections of a memory cell array including NAND memory strings.

FIG. 3 illustrates an example of a schematic diagram of some peripheral circuits.

FIG. 4 illustrates an example circuit for performing program operations.

FIG. 5 illustrates a schematic diagram of an example voltage transfer circuit.

FIG. 6 is a timing diagram illustrating voltage waveforms at various locations in an example program operation for a selected word line.

FIG. 7 is a timing diagram illustrating voltage waveforms at various locations in another example program operation for a selected word line.

FIGS. 8A-8B show a timing diagram illustrating voltage waveforms at various locations in another example program operation for a selected word line.

FIG. 9 illustrates a flowchart of an example method for performing a program operation.

FIG. 10 illustrates a block diagram of an example system having a memory device.

FIG. 11A illustrates a diagram of a memory card having a memory device.

FIG. 11B illustrates a diagram of a solid-state drive (SSD) having a memory device.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper and higher-density memory devices, memory devices (e.g., a 3D NAND flash memory) can be formed to have multiple decks, and each deck can have a large number of layers. The large number of layers and the high aspect ratio of such memory device may bring challenges to the manufacturing process. As a die size of the memory device continues to shrink, a string driver, which occupies a portion of the memory device, also faces increasing pressure to reduce in size. Faster program times (tProg) are desired in memory devices such as TLC (Triple-Level Cell) devices. However, after up and down ramping cycles during erase/program operations, the string driver may suffer hot carrier injection (HCI) issues, which can lead to threshold voltage shifts in transistors of the string driver and a subsequent reduction in ramping speed. Therefore, reducing performance decline and ensuring that the memory device can still provide effective functionality by the end of its life cycle without increasing the string driver size has become a common challenge across the industry.

In one or more implementations of the present disclosure, an example method for programming memory cells of a memory device is provided. By taking advantage of the coupling between adjacent word lines, voltages at word lines adjacent to a selected word line can be controlled to help ramp up a voltage at the selected word line during a program operation. Implementations of the present disclosure can provide one or more of the following technical advantages and/or benefits. In some implementations, no hardware modifications are required as the described techniques can be implemented in firmware changes to memory controllers or control circuits. The HCI issue of the string driver can be mitigated. Test results show that in some implementations, improvements to tProg can result in a saving of 2 microseconds (μs) per page without increasing the die size of the memory device. The test results also show that in some instances the string driver HCI issue at the end of life of the memory device can be improved by 0.4 pulse.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

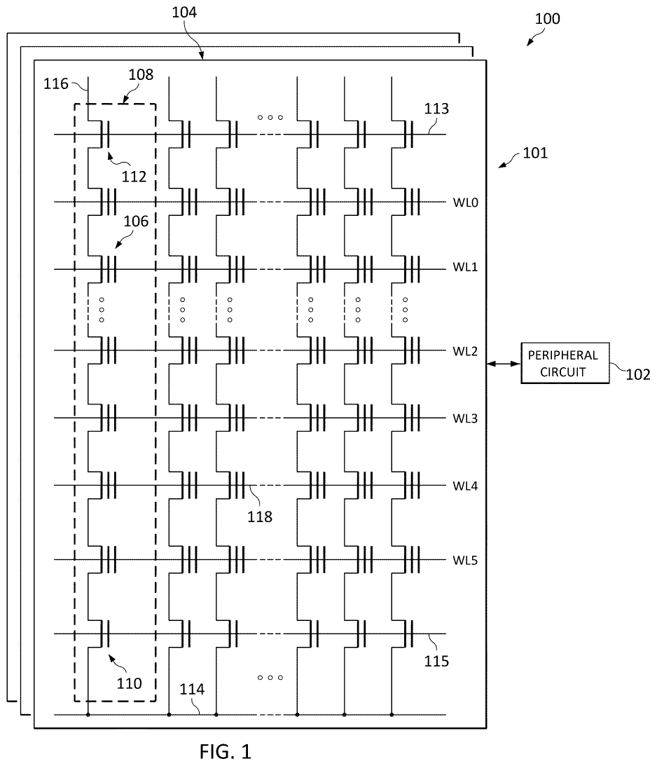

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND flash memory cell array in which memory cells 106 are provided in the form of an array of memory strings 108 (e.g., NAND memory strings) each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 can be referred to as a bottom select gate (BSG), and DSG 112 can be referred to as a top select gate (TSG). BSG 110 and TSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, NAND memory strings 108 in the same block 104 have an array common source (ACS), according to some implementations. TSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage (e.g., above the threshold voltage of the transistor having TSG 112) or a deselect voltage (e.g., 0 V) to respective TSG 112 through one or more TSG lines 113, and/or by applying a select voltage (e.g., above the threshold voltage of the transistor having BSG 110) or a deselect voltage (e.g., 0 V) to respective BSG 110 through one or more BSG lines 115. In some implementations, NAND memory string 108 includes the bottom memory cell abutted BSG 110 and the top memory cell abutted TSG 112, where the bottom memory cell is coupled to the bottom word line, for example, WL5 shown in FIG. 1, and the top memory cell is coupled to the top word line, for example, WL0 shown in FIG. 1.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Verase), such as a high positive voltage (e.g., 20V or more). In some examples, erase operation may be performed at a half-block level, a quarter-block level, or a level having any suitable number of blocks or any suitable fractions of a block. Memory cells 106 of adjacent NAND memory strings 108 can be coupled through word lines 118 that select which row of memory cells 106 is affected by read and program operations. Example word lines shown in FIG. 1 include top word line WL0, WL1, WL2, WL3, WL4, and bottom word line WL5 that are between one or more TSG lines 113 and one or more BSG lines 115.

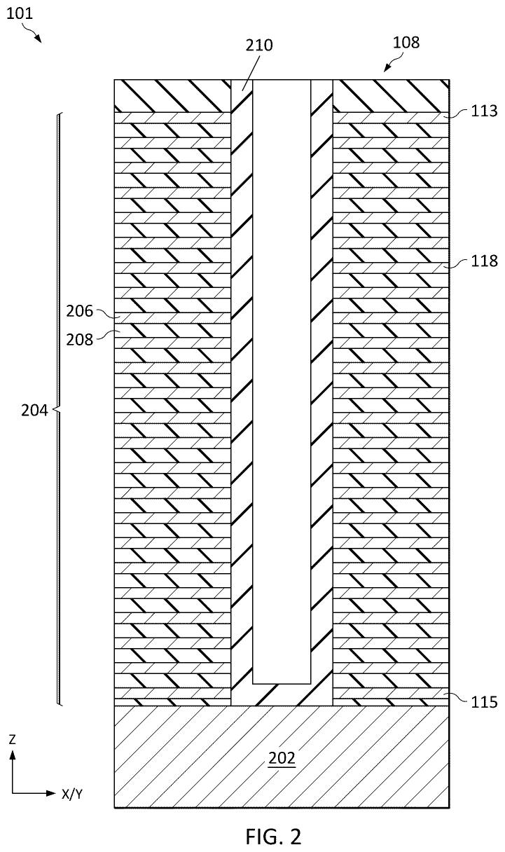

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding memory cells 106, TSG 112, or BSG 110, and can extend laterally as TSG line 113 at the top of memory stack 204, BSG line 115 at the bottom of memory stack 204, or word line 118 between TSG line 113 and BSG line 115.

As shown in FIG. 2, NAND memory string 108 includes a channel 210 extending vertically through memory stack 204. In some implementations, channel 210 includes multiple layers each formed of a different material (e.g., a semiconductor material or a dielectric material).

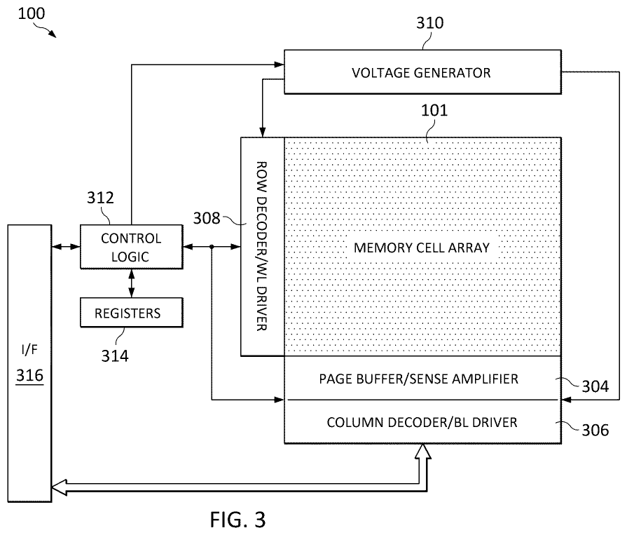

FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well. Peripheral circuits 102 can be coupled to memory cell array 101 through bit lines 116, word lines 118, source lines 114, BSG lines 115, and TSG lines 113 of FIG. 1. Peripheral circuits 102 can include any suitable analog, digital, and mixed-signal circuits for facilitating the operations of memory cell array 101 by applying and sensing voltage signals and/or current signals to and from each target memory cell 106 through bit lines 116, word lines 118, source lines 114, BSG lines 115, and TSG lines 113. Peripheral circuits 102 can include various types of peripheral circuits formed using metal-oxide-semiconductor (MOS) technologies.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive BSG lines 115 and TSG lines 113 as well. As described below in detail, row decoder/word line driver 308 is configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. As described below in detail, the status registers of registers 314 can include one or more registers configured to store open block information indicative of the open block(s) of all blocks 104 in memory cell array 101. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

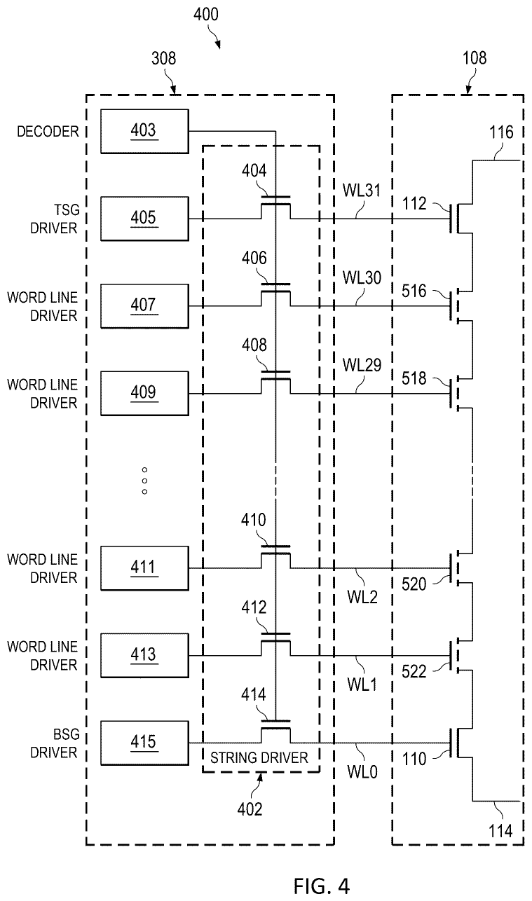

FIG. 4 illustrates an example circuit 400 for performing program operations, according to some aspects of the present disclosure. Circuit 400 can be part of memory device 100 in FIG. 1. As shown in FIG. 4, circuit 400 includes row decoder/word line driver 308 and is coupled to at least one memory string 108 (e.g., a NAND memory string). Circuit 400 can be part of a peripheral circuit of a memory device (e.g., peripheral circuit 102 of FIG. 1 or the peripheral circuits shown in FIG. 3). In some implementations, circuit 400 further includes a voltage generator (e.g., voltage generator 310 of FIG. 3, which is not shown in FIG. 4) Memory string 108 includes TSG 112, memory cells 416-424, and BSG 110 coupled in series. TSG 112 is coupled to bit line 116, and BSG 110 is coupled to source line 114. The transistors and memory cells in memory string 108 are coupled to row decoder/word line driver 308 through WL0-WL31 and are configured to receive control voltages from row decoder/word line driver 308. Row decoder/word line driver 308 includes a string driver 402, decoder 403, and drivers 405-415. Decoder 403 is configured to select and control transistors of string driver 402 and is coupled to a voltage generator (e.g., voltage generator 310 of FIG. 3). Driver 405 can be called TSG driver, which is configured to provide a control voltage to TSG 112. Driver 415 can be called BSG driver, which is configured to provide a control voltage to BSG 110. Drivers 407-413 are word line drivers, which are configured to provide control voltages to WL1-WL30. In some implementations, word line drivers 407-413 are coupled between a voltage generator (e.g., voltage generator 310 of FIG. 3) and WL1-WL30 and are configured to provide voltages from the voltage generator to WL1-WL30. String driver 402 includes driving transistors 404-414 coupled in parallel through their gates. Controlled by a voltage from decoder 403, each of driving transistors 404-414 is configured to pass a voltage from one of the drivers 405-415 to a corresponding transistor in memory string 108. In some implementations, each of the driving transistors 404-414 can include a suitable semiconductor transistor, such as a Bipolar Junction Transistor (BJT) or a Field Effect Transistor (FET). In some implementations, each of the driving transistors 404-414 can be a metal-oxide-semiconductor field effect transistor (MOSFET), such as an n-channel MOSFET.

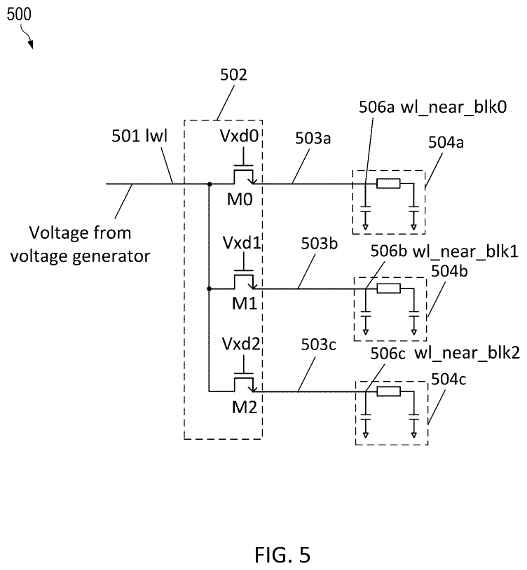

FIG. 5 illustrates a schematic diagram of an example voltage transfer circuit 500. The voltage transfer circuit 500 can include a row decoder/word line driver 502 coupled to different word lines (e.g., word lines 503a, 503b, and 503c as shown in FIG. 5). The row decoder/word line driver 502 can be an implementation of the row decoder/word line driver 308 of FIG. 3 and FIG. 4. A circuit 504a represents an equivalent circuit for memory cells coupled to the word line 503a (e.g., in the same memory page). The circuit 504a can include two capacitors connected in parallel and a resistor connected in series with one of the capacitors. Similarly, circuits 504b and 504c can represent equivalent circuits for memory cells coupled to the word lines 503b and 503c, respectively. In some implementations, the word lines 503a, 503b, and 503c may belong to different memory blocks. For example, the word line 503a belongs to memory block 0, the word line 503b belongs to memory block 1, and the word line 503c belongs to memory block 2. The row decoder/word line driver 502 can include driving transistors M0, M1, and M2. Each of M0, M1, and M2 can be an example of one of the driving transistors 406-412 of FIG. 4 and can be coupled to a respective word line. The row decoder/word line driver 502 can be configured to pass a voltage (e.g., provided by a voltage generator 310) to a selected word line. In some implementations, the row decoder/word line driver 502 can select a memory block, a global word line (gwl, which is not shown in FIG. 5), a local word line (lwl) 501, or one of the word lines 503a, 503b, and 503c according to a control signal (e.g., sent by control logic 312 of FIG. 3). According to the control signal, a gate select voltage (e.g., Vxd0, Vxd1, and Vxd2) may be applied to a gate of a driving transistor (e.g., M0, M1, and M2). A voltage at a near word line node (e.g., nodes 506a, 506b, and 506c) represents an actual voltage applied to a selected word line. When a driving transistor is turned on by the gate select voltage, the voltage at a corresponding near word line node can follow a voltage from the local word line (e.g., provided by the voltage generator).

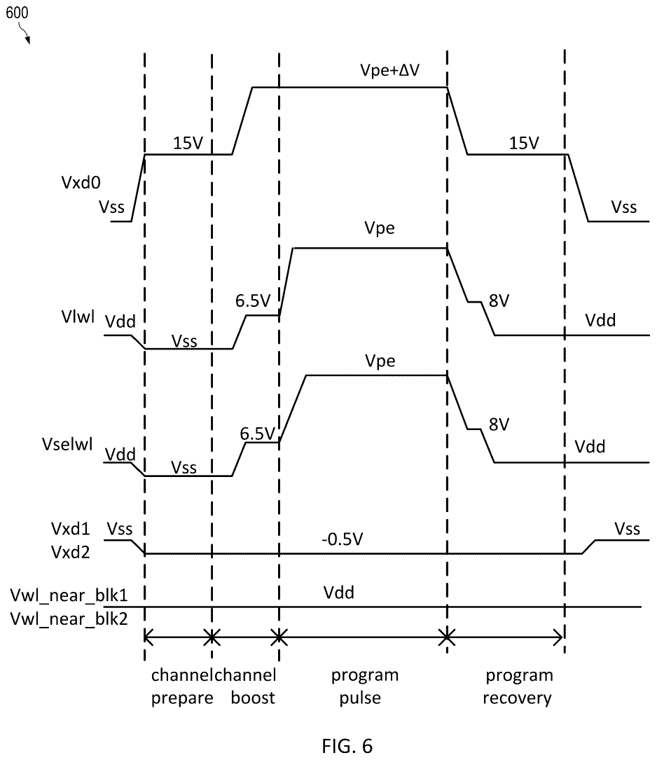

FIG. 6 is a timing diagram 600 illustrating voltage waveforms at various locations in an example program operation for a selected word line, according to some implementations of the present disclosure. In this example, a word line (e.g., word line 503a) in memory block 0 is selected, and memory blocks 1 and 2 are unselected. The program operation can include multiple phases, for example, a channel prepare phase, a channel boost phase, a program pulse phase, and a program recovery phase.

In the channel prepare phase, the voltage generator may generate voltages required in the latter phases, such as voltages applied to gates of various transistors and a channel boost voltage. The driving transistors M1 and M2 can be turned off as the memory blocks 1 and 2 are unselected. Thus, the gate select voltages Vxd1 and Vxd2 can be kept at a lower level (e.g., −0.5V as shown in FIG. 6), and Vwl_near_blk1 and Vwl_near_blk2, which represent voltages at near word line nodes 506b and 506c, can be kept at Vdd. The gate select voltage Vxd0 increases from Vss to a higher level (e.g., 15V as shown in FIG. 6) to turn on the driving transistor M0. A local word line voltage Vlwl (e.g., the voltage at the local word line 501 of FIG. 5) decreases from Vdd to Vss. A selected word line voltage Vselwl (e.g., the voltage at the selected word line 503a or at the near word line node 506a) also decreases from Vdd to Vss as the driving transistor M0 is turned on.

In the channel boost phase, Vlwl can increase from Vss to a channel boost voltage (e.g., 6.5V as shown in FIG. 6). Vxd0 increases from 15V to a higher voltage to keep M0 turned on. For example, the higher voltage can be a target program voltage Vpe plus a value (e.g., ΔV) larger than a threshold voltage of M0. Vselwl follows Vlwl and also increases from Vss to the channel boost voltage. A drain to source voltage Vds of M0 is at a high level as Vselwl increases slower than Vlwl does. In some implementations, the high gate voltage (e.g., Vxd0) and the high drain to source voltage (e.g., Vds) of M0 can cause hot carrier injection (HCI), which refers to high-energy charge carriers (electrons or holes) being injected into a gate oxide of M0, thereby shifting in the threshold voltage of M0 and affecting the reliability of M0. In some instances, due to the HCI, Vselwl may ramp slower after several erase/program cycles.

In the program pulse phase, Vxd0 is kept at Vpe+ΔV. Vlwl can increase from the channel boost voltage to the target program voltage Vpe. Vselwl follows Vlwl and also increases from the channel boost voltage to Vpe. In the program recovery phase, Vxd0, Vwl, and Vselwl can ramp down to respective lower voltages.

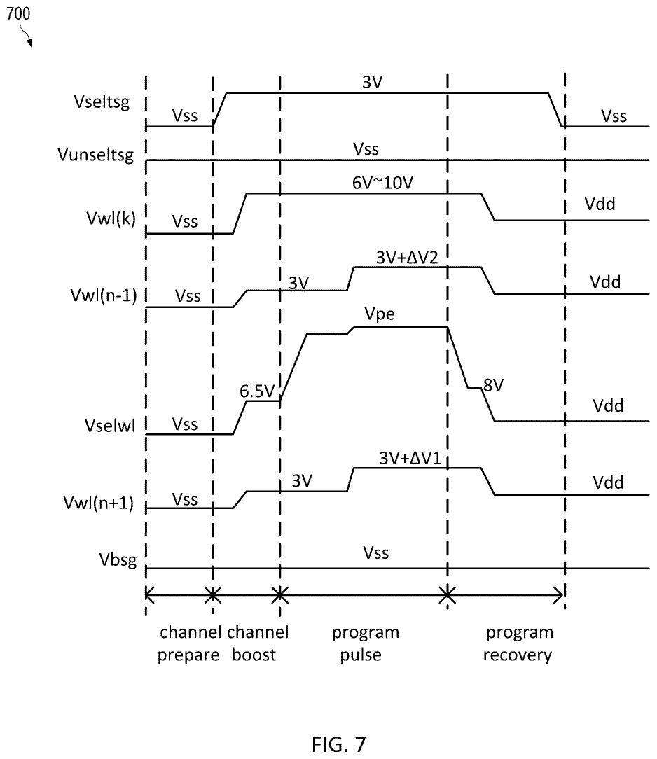

FIG. 7 is a timing diagram 700 illustrating voltage waveforms at various locations in another example program operation for a selected word line, according to some embodiments of the present disclosure. In this example, the selected word line's index is n. By taking advantage of the coupling between adjacent word lines, voltages at word lines adjacent to the selected word line can be controlled to help ramp up a voltage at the selected word line. In the program operation, Vunseltsg, which is a voltage at an unselected TSG (e.g., the TSG in an unselected memory string) and a BSG voltage Vbsg are kept at Vss.

In a channel prepare phase of the program operation, Vseltsg, which is a voltage at a selected TSG (e.g., the TSG in a selected memory string), is kept at Vss. Voltages at word lines (including the selected word line and unselected word lines) are also Vss.

In a channel boost phase of the program operation, a selected word line voltage Vselwl increases from Vss to a channel boost voltage. The channel boost voltage can be in a range between 6V and 10V. For example, the channel boost voltage can be 6.5V. A gate select voltage Vxd0 and a local word line voltage Vlwl, which are not shown in FIG. 7, can be the same as or similar to those described above with respect to FIG. 6. In some implementations (not shown in FIG. 7), voltages at unselected word lines can also increase from Vss to the channel boost voltage. In some other implementations, as shown in FIG. 7, voltages (e.g., Vwl(n−1) and Vwl(n+1)) at word lines (e.g., word line n−1 and word line n+1) adjacent to the selected word line n can increase to a value (e.g., 3V) smaller than the channel boost voltage, while voltages Vwl(k) at other word lines (e.g., word line k, k≠n−1, n, and n+1) rise to the channel boost voltage. Vseltsg can increase from Vss to 3V so that a lower voltage (e.g., Vss) at a bit line (e.g., bit line 116 of FIG. 1) coupled to the selected TSG can be passed through while a higher voltage (e.g., Vdd) at the bit line can be blocked.

In a program pulse phase of the program operation, Vselwl can increase from the channel boost voltage to a target program voltage Vpe. In some implementations, before Vselwl reaches Vpe, Vwl(n+1) and Vwl(n−1) can be controlled to increase (e.g., from 3V to a higher level 3V+ΔV1 or 3V+ΔV2). A coupling capacitor can exist between adjacent word lines. Thus, due to the coupling between adjacent word lines n−1, n, and n+1, when Vwl(n−1) and Vwl(n+1) increases, Vselwl can follow Vwl(n−1) and Vwl(n+1) and thus can ramp up faster. Although not shown in FIG. 7, the gate select voltage Vxd0 and the local word line voltage Vlwl in the program pulse phase can be the same as or similar to those described above with respect to FIG. 6. Thus, for similar reasons, the program operation of FIG. 7 may also cause HCI in the program pulse phase. In a program recovery phase of the program operation, Vseltsg and voltages at different word lines can ramp down to respective lower voltages.

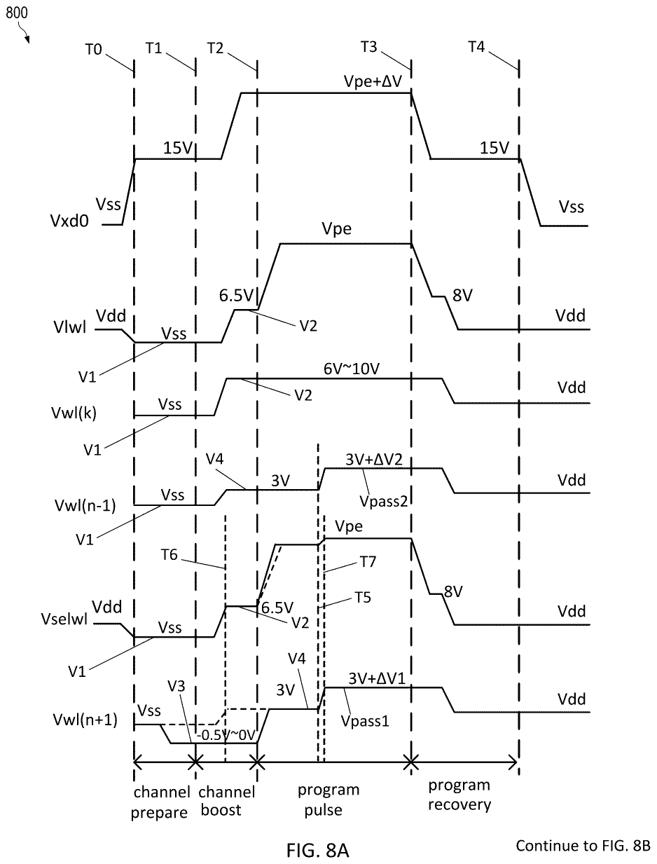

FIGS. 8A-8B show a timing diagram 800 illustrating voltage waveforms at various locations in another example program operation for a selected word line, according to some implementations of the present disclosure. In this example, a word line (e.g., word line 503a of FIG. 5) in memory block 0 is selected, and memory blocks 1 and 2 are unselected. The selected word line's index is n. The program operation can include multiple phases, for example, a channel prepare phase, a channel boost phase, a program pulse phase, and a program recovery phase. As shown in FIG. 8B, in the program operation, a voltage at an unselected TSG Vunseltsg and a BSG voltage Vbsg can be kept at Vss. In addition, in the program operation, gate select voltages for unselected memory blocks (e.g., Vxd1 and Vxd2 in FIG. 8B) can be kept at a lower level (e.g., −0.5V), and voltages at near word line nodes (e.g., Vwl_near_blk1 at node 506b and Vwl_near_blk2 at node 506c) can be kept at Vdd (e.g., as shown in FIG. 8B).

The channel prepare phase begins at time T0 and ends at time T1. A gate select voltage Vxd0 can increase from Vss to a higher level (e.g., 15V as shown in FIG. 8A) to turn on a driving transistor (e.g., M0) coupled to the selected word line before the channel prepare phase, and can be kept at the higher level in the channel prepare phase. A local word line voltage Vlwl can decrease from Vdd to voltage V1 (e.g., Vss) before the channel prepare phase and can be kept at V1 in the channel prepare phase. A selected word line voltage Vselwl (e.g., the voltage at the selected word line n) also decreases from Vdd to V1 before the channel prepare phase and is kept at V1 in the channel prepare phase, because the driving transistor M0 is turned on.

In this example, each word line is programmed one by one according to an ascending order of the word line indices. That it, memory cells coupled to the selected word line n are being programmed in the current program operation. In addition, memory cells coupled to word line i (i>n) have not been programmed in the current program operation yet and are to be programmed, and memory cells coupled to word line (j<n) have been programmed in the current program operation already. It is understood that while this example is for illustration purpose and is not intended to be construed in a limiting sense, in some implementations, each word line can be programmed one by one according to a descending order of the word line indices. For example, memory cells coupled to word line i (i>n) may have been programmed in the current program operation already, and memory cells coupled to word line (j<n) may have not been programmed in the current program operation yet and are to be programmed.

In this example, word lines n−1 and word line n+1 are adjacent to the selected word line n in the memory string. As shown in FIG. 8A, voltage Vwl(n+1) at word line n+1 can be V1 in the beginning of the channel prepare phase and can decrease to voltage V3 at some point in the channel prepare phase (e.g., between T0 and T1). In some implementations, V3 can be lower than or equal to V1. In some instances, V3 can be lower than V1. For example, V1 can be Vss (e.g., 0V), and V3 can be −0.5V. Voltage Vwl(n−1) at word line n−1 can be V1 in the channel prepare phase. Voltages Vwl(k) at other word lines (e.g., word line k, k≠n−1, n, and n+1) are also kept at V1 in the channel prepare phase. It is understood that the various voltages shown in FIGS. 8A-8B (e.g., word line voltages, Vseltsg, and Vbsg in the channel prepare phase between T0 and T1) are only used for illustration purposes, and are not intended to be construed in a limiting sense. In practice, the voltage values or voltage plans may be adjusted according to the actual situation. For example, any suitable voltage plan for the channel prepare phase can be applied. The same notion for describing the voltages is applied throughout the present disclosure.

The channel boost phase begins at time T1 and ends at time T2. At some point in the channel boost phase, Vlwl can increase from V1 to voltage V2 (also referred to as a channel boost voltage). For example, as shown in FIG. 8A, the channel boost voltage V2 can be in a range between 6V and 10V. In some instances, V2 can be 6.5V. Vxd0 increases from 15V to a higher voltage to keep M0 turned on. For example, the higher voltage can be a target program voltage Vpe plus a value (e.g., ΔV) larger than a threshold voltage of M0. Vselwl follows Vlwl and increases from V1 to the channel boost voltage V2. As shown in FIG. 8A, Vwl(k) (k≠n−1, n, and n+1) increases from V1 to V2 at some point in the channel boost phase. At some point in the channel boost phase, Vwl(n−1) can increase from V1 to voltage V4 (e.g., 3V) that is smaller than the channel boost voltage V2. Vwl(n+1) can be kept at V3 in the channel boost phase. As shown in FIG. 8B, in the channel boost phase, Vseltsg can increase from Vss to 3V so that a lower voltage (e.g., Vss) at a bit line coupled to the selected TSG can be passed through while a higher voltage (e.g., Vdd) at the bit line can be blocked.

The program pulse phase begins at time T2 and ends at time T3. In the program pulse phase, Vxd0 is kept at Vpe+ΔV. At T2, Vlwl starts to increase from the channel boost voltage V2. Vlwl reaches the target program voltage Vpe at some point between T2 and T3 and stays at Vpe till T3. Vselwl follows Vlwl and also starts to increase from the channel boost voltage V2 at T2. The ramping up of Vselwl can be boosted by changes to Vwl(n−1) and Vwl(n+1) due to the coupling between adjacent word lines n−1, n, and n+1. Vwl(n−1) and Vwl(n+1) can be configured to increase in the program pulse phase. In some implementations, Vwl(n+1) starts to increase from V3 at T2. At some point between T2 and T3, Vwl(n+1) reaches V4. At a later point (e.g., time T5) in the program pulse phase, Vwl(n−1) and Vwl(n+1) start to increase from V4 (e.g., 3V). Vwl(n+1) can increase from V4 to a first pass voltage Vpass1 (e.g., 3V+ΔV1), and Vwl(n−1) can increase from V4 to a second pass voltage Vpass2 (e.g., 3V+ΔV2). Accordingly, as shown in FIG. 8A, Vselwl follows Vlwl and also increases from the channel boost voltage V2 to Vpe. The ramping of Vselwl becomes faster when at least one of Vwl(n−1) and Vwl(n+1) increases.

The program recovery phase begins at T3 and ends at T4. In the program recovery phase, as shown in FIG. 8A, Vxd0, Vlwl, Vsclwl, and Vwl(k) (k #n) can ramp down to respective lower voltages.

The waveforms of Vwl(n+1) and Vselwl in FIG. 7 are reproduced as dashed lines in FIG. 8A. Compared to the example in FIG. 7, Vselwl in the example of FIG. 8A increases faster because Vwl(n+1) increases from V3 to V4 in the beginning of the program pulse phase. As Vselwl is the voltage at the source of the driving transistor M0, faster ramping up of Vselwl can help decrease a drain to source voltage Vds and a gate to source voltage Vgs of M0, thereby mitigating the HCI issue in the program pulse phase.

In some implementations, memory cells coupled to word line n−1 have been programmed, and memory cells coupled to word line n+1 have not been programmed (e.g., they are in erase states). Thus, Vpass2 can be configured to be lower than Vpass1 because higher Vpass2 may affect the distribution of threshold voltages of the memory cells coupled to word line n−1 and may cause damage to data programmed into these memory cells.

In some implementations, Vselwl starts to increase from V2 and Vwl(n+1) starts to increase from V3 at a same time (e.g., at the beginning of the program pulse phase T2 as shown in FIG. 8A). In some other implementations, the increasing of Vselwl from V2 and the increasing of Vwl(n+1) from V3 may not be at the same time. For example, Vwl(n+1) can start to increase from V3 after Vselwl reaches V2 (e.g., at time T6) and before Vselwl reaches Vpe (e.g., at time T7). In other words, in some implementations, Vwl(n+1) can start to increase at any suitable point between T6 and T7.

In some implementations, more than one word lines (e.g., word lines n+2 and n+3) that are adjacent to the selected word line n and are not programmed yet in the current program operation can be provided a voltage similar to Vwl(n+1). In this way, more adjacent word lines can be utilized to help ramp up the selected word line voltage Vselwl. However, allowing more adjacent word lines to have a lower voltage in the channel boost phase may reduce the overall potential of the memory string. Thus, in practice, a suitable number of adjacent word lines can be selected and configured to have a voltage change similar to Vwl(n+1) of FIG. 8A. In some implementations, the suitable number can be determined based on experimental results.

It is understood that the values of V2, V3, and V4 in the example of FIGS. 8A-8B are for illustration purpose and are not intended to be construed in a limiting sense. In practice, any suitable values can be applied to these voltages. In some implementations, incremental step pulse program (ISPP) can be applied to the program operation, and thus for each ISPP program cycle, V2 and V4 may become higher than those in a previous ISPP program cycle.

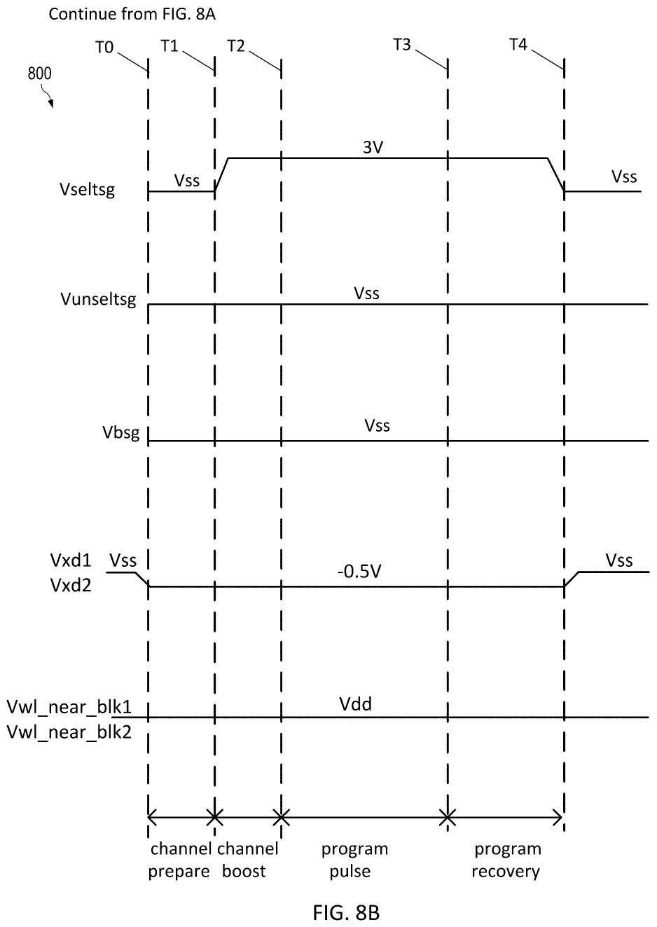

FIG. 9 illustrates a flowchart of an example method 900 for performing a program operation, in accordance with some aspects of the present disclosure. Method 900 can be performed by any suitable device or circuit disclosed herein.

As shown in FIG. 9, in operation 902, a voltage (e.g., Vselwl of FIG. 8A) of a first word line (e.g., the selected word line n) of a memory device is increased from a first voltage (e.g., V1) to a second voltage (e.g., V2) in a first time period (e.g., between T1 and T2).

In operation 904, the voltage of the first word line is increased from the second voltage to a target program voltage (e.g., Vpe) in a second time period (e.g., between T2 and T3).

In operation 906, a voltage (e.g., Vwl(n+1)) of a second word line (e.g., the word line n+1 as described with respect to FIGS. 8A-8B) of the memory device is increased from a third voltage (e.g., V3) to a fourth voltage (e.g., V4). The second word line is adjacent to the first word line. The voltage of the second word line starts to increase from the third voltage after the voltage of the first word line reaches the second voltage (e.g., at T6) and before the voltage of the first word line reaches the target program voltage (e.g., at T7).

In some implementations, the voltage of the first word line starts to increase from the second voltage and the voltage of the second word line starts to increase from the third voltage at a same time (e.g., at T2).

In some implementations, the voltage of the first word line starts to increase from the second voltage and the voltage of the second word line starts to increase from the third voltage at a beginning of the second time period (e.g., the beginning of the channel boost phase of FIGS. 8A-8B).

In some implementations, the method 900 further includes increasing a voltage (e.g., Vwl(n−1)) of a third word line (e.g., word line n−1 as described with respect to FIGS. 8A-8B) of the memory device from the first voltage to the fourth voltage (e.g., V4) in the first time period. The third word line is adjacent to the first word line.

In some implementations, memory cells coupled to the first word line are being programmed in a current program operation, memory cells coupled to the second word line have not been programmed in the current program operation yet, and memory cells coupled to the third word line have been programmed in the current program operation.

In some implementations, the method 900 further includes increasing the voltage of the second word line from the fourth voltage to a first pass voltage (e.g., Vpass1 of FIG. 8A) in the second time period (e.g., between T2 and T3). The method 900 further includes increasing the voltage of the third word line from the fourth voltage to a second pass voltage (e.g., Vpass2 of FIG. 8A) in the second time period. The first pass voltage can be higher than the second pass voltage.

In some implementations, the voltage of the second word line and the voltage of the third word line start to increase from the fourth voltage at a same time (e.g., at T5 of FIG. 8A).

In some implementations, the voltage of the second word line starts to increase from the third voltage (e.g., at T2) after the voltage of the third word line reaches the fourth voltage (at some point between T1 and T2).

In some implementations, the voltage of the second word line is kept at the third voltage during the first time period, and the third voltage (e.g., V3) is less than the first voltage (e.g., Vss).

In some implementations, the third voltage is less than or equal to 0V (e.g., −0.5V).

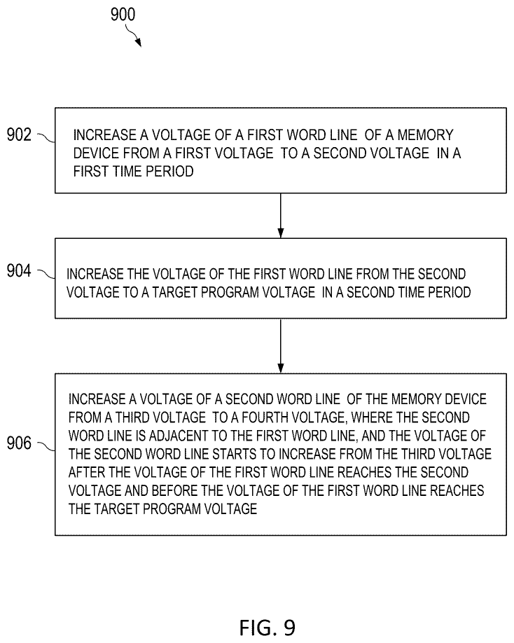

FIG. 10 illustrates an example of a block diagram of system 1000 having a memory device, according to some aspects of the present disclosure. System 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1000 can include a host 1008 and a memory system 1002 having one or more memory devices 1004 and a memory controller 1006. Host 1008 can be a processor of an electronic device, such as a central processing unit (CPU), or a system-on-chip (SoC), such as an application processor (AP). Host 1008 can be configured to send or receive data to or from memory devices 1004.

Memory device 1004 can be any memory device disclosed in the present disclosure. Memory controller 1006 is coupled to memory device 1004 and host 1008 and is configured to control memory device 1004, according to some implementations. Memory controller 1006 can manage the data stored in memory device 1004 and communicate with host 1008. In some implementations, memory controller 1006 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1006 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1006 can be configured to control operations of memory device 1004, such as read, erase, and program operations. Memory controller 1006 can also be configured to manage various functions with respect to the data stored or to be stored in memory device 1004 including, but not limited to bad-block management, garbage collection, logical-to-physical address conversion, wear leveling, etc. In some implementations, memory controller 1006 is further configured to process error correction codes (ECCs) with respect to the data read from or written to memory device 1004. Any other suitable functions may be performed by memory controller 1006 as well, for example, formatting memory device 1004.

Memory controller 1006 can communicate with an external device (e.g., host 1008) according to a particular communication protocol. For example, memory controller 1006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

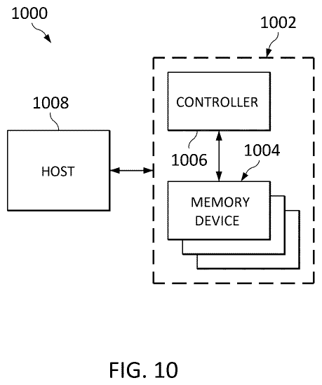

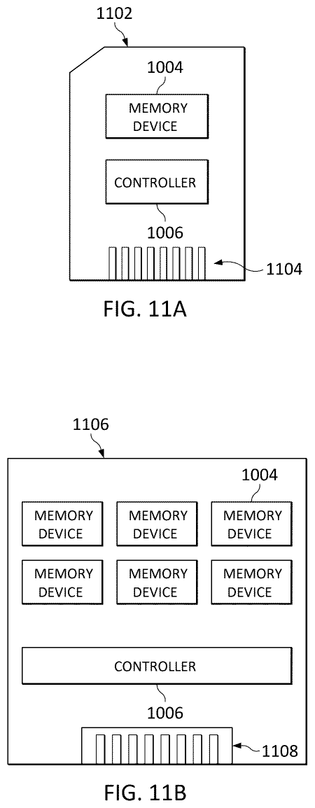

Memory controller 1006 and one or more memory devices 1004 can be integrated into various types of storage devices, for example, be included in the same package, such as a universal Flash storage (UFS) package or an eMMC package. That is, memory system 1002 can be implemented and packaged into different types of end electronic products. In one example as shown in FIG. 11A, memory controller 1006 and a single memory device 1004 may be integrated into a memory card 1102. Memory card 1102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1102 can further include a memory card connector 1104 coupling memory card 1102 with a host (e.g., host 1008 in FIG. 10). In another example as shown in FIG. 11B, memory controller 1006 and multiple memory devices 1004 may be integrated into an SSD 1106. SSD 1106 can further include an SSD connector 1108 coupling SSD 1106 with a host (e.g., host 1008 in FIG. 10). In some implementations, the storage capacity and/or the operation speed of SSD 1106 is greater than those of memory card 1102.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for case of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method for programming memory cells of a memory device, wherein the method comprises:
increasing a voltage of a first word line of the memory device from a first voltage to a second voltage in a first time period;
increasing the voltage of the first word line from the second voltage to a target program voltage in a second time period; and
increasing a voltage of a second word line of the memory device from a third voltage to a fourth voltage, wherein the second word line is adjacent to the first word line, and the voltage of the second word line starts to increase from the third voltage after the voltage of the first word line reaches the second voltage and before the voltage of the first word line reaches the target program voltage.

2. The method of claim 1, wherein the voltage of the first word line starts to increase from the second voltage and the voltage of the second word line starts to increase from the third voltage at a same time.

3. The method of claim 2, wherein the voltage of the first word line starts to increase from the second voltage and the voltage of the second word line starts to increase from the third voltage at a beginning of the second time period.

4. The method of claim 1, further comprising:
increasing a voltage of a third word line of the memory device from the first voltage to the fourth voltage in the first time period, wherein the third word line is adjacent to the first word line.

5. The method of claim 4, wherein memory cells coupled to the first word line are being programmed in a current program operation, memory cells coupled to the second word line have not been programmed in the current program operation yet, and memory cells coupled to the third word line have been programmed in the current program operation.

6. The method of claim 4, further comprising:
increasing the voltage of the second word line from the fourth voltage to a first pass voltage in the second time period; and
increasing the voltage of the third word line from the fourth voltage to a second pass voltage in the second time period, wherein the first pass voltage is higher than the second pass voltage.

7. The method of claim 6, wherein the voltage of the second word line and the voltage of the third word line start to increase from the fourth voltage at a same time.

8. The method of claim 4, wherein the voltage of the second word line starts to increase from the third voltage after the voltage of the third word line reaches the fourth voltage.

9. The method of claim 1, wherein the voltage of the second word line is kept at the third voltage during the first time period, and the third voltage is less than the first voltage.

10. The method of claim 1, wherein the third voltage is less than or equal to 0 volt (V).

11. A memory device comprising:
a memory block comprising a first word line and a second word line adjacent to the first word line; and
a peripheral circuit comprising a voltage generator and a string driver, wherein the peripheral circuit is configured to:
increase a voltage of the first word line from a first voltage to a second voltage in a first time period;
increase the voltage of the first word line from the second voltage to a target program voltage in a second time period; and
increase a voltage of the second word line from a third voltage to a fourth voltage, wherein the voltage of the second word line starts to increase from the third voltage after the voltage of the first word line reaches the second voltage and before the voltage of the first word line reaches the target program voltage.

12. The memory device of claim 11, wherein the voltage of the first word line starts to increase from the second voltage and the voltage of the second word line starts to increase from the third voltage at a beginning of the second time period.

13. The memory device of claim 11, wherein the memory block further comprises a third word line adjacent to the first word line, and wherein the peripheral circuit is further configured to:
increase a voltage of the third word line from the first voltage to the fourth voltage in the first time period.

14. The memory device of claim 13, wherein memory cells coupled to the first word line are being programmed in a current program operation, memory cells coupled to the second word line have not been programmed in the current program operation yet, and memory cells coupled to the third word line have been programmed in the current program operation.

15. The memory device of claim 13, wherein the peripheral circuit is further configured to:
increase the voltage of the second word line from the fourth voltage to a first pass voltage in the second time period; and
increase the voltage of the third word line from the fourth voltage to a second pass voltage in the second time period.

16. The memory device of claim 15, wherein the voltage of the second word line and the voltage of the third word line start to increase from the fourth voltage at a same time.

17. The memory device of claim 13, wherein the voltage of the second word line starts to increase from the third voltage after the voltage of the third word line reaches the fourth voltage.

18. The memory device of claim 11, wherein the third voltage is less than or equal to 0 volt (V).

19. The memory device of claim 11, wherein the voltage of the second word line is kept at the third voltage during the first time period, and the third voltage is less than or equal to the first voltage.

20. A memory system comprising a memory device and a memory controller configured to control the memory device, wherein the memory device comprises:
a memory block comprising a first word line and a second word line adjacent to the first word line; and
a peripheral circuit comprising a voltage generator and a string driver, wherein the peripheral circuit is configured to:
increase a voltage of the first word line from a first voltage to a second voltage in a first time period;
increase the voltage of the first word line from the second voltage to a target program voltage in a second time period; and
increase a voltage of the second word line from a third voltage to a fourth voltage, wherein the voltage of the second word line starts to increase from the third voltage after the voltage of the first word line reaches the second voltage and before the voltage of the first word line reaches the target program voltage.
